(19) United States
(12) Patent Application Publication
(10) Pub. No.: US 2026/0086146 A1
(43) Pub. Date: Mar. 26, 2026

(54) VOLTAGE SENSING FAILURE DETECTION

(71) Applicant: Micron Technology, Inc., Boise, ID (US)

(72) Inventors: Massimiliano Patriarca, Milano (IT); William P. Yu, Boise, ID (US); William A. Lendvay, Boise, ID (US)

(21) Appl. No.: 19/331,497

(22) Filed: Sep. 17, 2025

Related U.S. Application Data
(60) Provisional application No. 63/699,215, filed on Sep. 26, 2024.

(51) Int. Cl. G01R 31/28

(52) U.S. Cl. CPC G01R 31/2884

(57) ABSTRACT

Sensing for failure detection at a memory controller is described herein. An example memory system includes a memory device, a memory system controller, and an edge connector. The memory system controller can be configured to detect an input voltage or an input current at a pin on a memory system controller, wherein the pin on the memory system controller is coupled to a circuit including a light emitting diode (LED). The memory controller can be configured to detect an output voltage or an output current at a pin on a memory system edge connector, wherein the pin on the memory system edge connector is coupled to the circuit. A fault in the circuit can be detected based on the detected input voltage or input current at the pin on the memory system controller and the detected output voltage or the output current of the pin on the memory system edge connector.

### PRIORITY INFORMATION

This Application claims the benefits of U.S. Provisional Application Number 63/699,215, filed on September 26, 2024, the contents of which are incorporated herein by reference.

### TECHNICAL FIELD

The present disclosure relates generally to memory, and more particularly, to systems, apparatuses, and methods associated with sensing for failure detection.

### BACKGROUND

Memory devices are typically provided as internal, semiconductor, integrated circuits and/or external removable devices in computers or other electronic devices. There are many different types of memory including volatile and non-volatile memory. Volatile memory can require power to maintain its data and can include random-access memory (RAM), dynamic random access memory (DRAM), and synchronous dynamic random access memory (SDRAM), among others. Non-volatile memory can provide persistent data by retaining stored data when not powered and can include NAND flash memory, NOR flash memory, read only memory (ROM), and resistance variable memory such as phase change random access memory (PCRAM), resistive random access memory (RRAM), magnetic random access memory (MRAM), and programmable conductive memory, among others.

Memory devices can be utilized as volatile and non-volatile memory for a wide range of electronic applications in need of high memory densities, high reliability, and low power consumption. Non-volatile memory may be used in, for example, personal computers, portable memory sticks, solid state drives (SSDs), digital cameras, cellular telephones, portable music players such as MP3 players, and movie players, among other electronic devices.

Various computing systems can include processing resources that are coupled to memory (e.g., a memory system), which is associated with executing a set of instructions (e.g., a program, applications, etc.).

### BRIEF DESCRIPTION OF THE DRAWINGS

FIG. 1 illustrates a block diagram of a computing system including a memory system in accordance with a number of embodiments of the present disclosure.

FIG. 2 illustrates a block diagram of a memory system including an edge connector and a light emitting diode (LED) circuit in accordance with a number of embodiments of the present disclosure.

FIG. 3 illustrates a schematic diagram of a light emitting diode (LED) circuit in accordance with a number of embodiments of the present disclosure.

FIG. 4 illustrates a logic table associated with the inputs and outputs of a light emitting diode (LED) circuit in accordance with a number of embodiments of the present disclosure.

### DETAILED DESCRIPTION

The present disclosure includes systems, apparatuses, and methods associated with sensing for failure detection. A memory system can include a memory device, a memory system controller, and an edge connector. The memory system controller can be configured to detect an input voltage or an input current at a pin on a memory system controller, wherein the pin on the memory system controller is coupled to a circuit including a light emitting diode (LED) (e.g., an LED circuit). The memory system controller can be configured to detect an output voltage or an output current at a pin on a memory system edge connector, wherein the pin on the memory system edge connector is coupled to the circuit. A fault in the circuit can be detected based on the detected input voltage or input current at the pin on the memory system controller and the detected output voltage or the output current of the pin on the memory system edge connector.

An LED circuit can be coupled to a general purpose input/output (GPIO) pin on an edge connector. The LED in the LED circuit can be used to monitor signals from the host by being activated in response to receiving a signal from the host and deactivated in response to not receiving a signal from the host. A fault or failure can occur in the LED circuit such that the LED is not activated even when the LED circuit is receiving signals from the host. If the LED circuit does not have a connection to the memory controller, the memory controller is not able to determine whether the LED circuit is receiving signals from the host via the LED circuit. Also, if the LED circuit does not have a connection to the memory system controller, faults or failures in the LED circuit can go undetected and the LED circuit may incorrectly indicate that the edge connector and/or LED circuit is not receiving signals from the host.

In a number of embodiments of the present disclosure, the LED circuit can be coupled to a pin (e.g., a GPIO pin) on an edge connector and be coupled to a pin (e.g., a GPIO pin) on a memory system controller. Faults or failures in the LED circuit can be detected by the memory system controller based on the signals detected at the pin on the edge connector and the pin on the memory controller. When a signal at the pin on the edge connector at a high level (e.g., a voltage or current that corresponds to a signal from the host) is detected and a signal at the pin on the memory controller at a low level (e.g., a voltage or current that corresponds to an absence of a signal from a voltage source) is detected, the memory system controller can determine (e.g., detect) that a fault or failure in the LED circuit does not exist. When a signal at the pin on the edge connector at a low level (e.g., a voltage or current that corresponds to an absence of a signal from the host) is detected and a signal at the pin on the memory controller at a high level (e.g., a voltage or current that corresponds to a voltage source) is detected, the memory system controller can determine (e.g., detect) that a fault or failure in the LED circuit does not exist.

When a signal at the pin on the edge connector at a high level (e.g., a voltage or current that corresponds to a signal from the host) is detected and a signal at the pin on the memory controller at a high level (e.g., a voltage or current that corresponds to a signal from a voltage source) is detected, the memory system controller can determine (e.g., detect) that a fault or failure in the LED circuit exists. When a signal at the pin on the edge connector at a low level (e.g., a voltage or current that corresponds to an absence of a signal from the host) is detected and a signal at the pin on the memory controller at a low level (e.g., a voltage or current that corresponds to an absence of a signal from a voltage source) is detected, the memory system controller can determine (e.g., detect) that a fault or failure in the LED circuit exists.

In a number of embodiments, the LED circuit can be used to send commands from the host to the memory system controller via pulse code. The LED circuit can be used for asynchronous serial inputs from the host to the memory system controller. The host can send signal pulses that correspond to binary inputs of commands that can be received, stored, and executed by the memory system controller.

As used herein, “a”, “an”, or “a number of” can refer to one or more of something, and “a plurality of” can refer to two or more such things. For example, a memory device can refer to one or more memory devices, and a plurality of memory devices can refer to two or more memory devices.

As used herein, an “apparatus” can refer to, but is not limited to, a variety of structures or combinations of structures, such as circuit or circuitry, a die or dice, a module, or modules, a device or devices, or a system of systems. For example, the memory system 108, the memory system controller 110, the memory components 116-N, may separately or collectively be referred to as an “apparatus.”

The figures herein follow a numbering convention in which the first digit or digits correspond to the drawing figure number and the remaining digits identify an element or component in the drawing. Analogous elements within a Figure may be referenced with a hyphen and extra numeral or letter. Such analogous elements may be generally referenced without the hyphen and extra numeral or letter. For example, elements 112-0₀, 112-1₀, …, 112-N₀ may collectively be referenced as 112. As used herein, the designators “N” and “X”, particularly with respect to reference numerals in the drawings, indicate that a number of the particular feature so designated can be included. As will be appreciated, elements shown in the various embodiments herein can be added, exchanged, and/or eliminated so as to provide a number of additional embodiments of the present disclosure. In addition, as will be appreciated, the proportion and relative scale of the elements provided in the figures are intended to illustrate certain embodiments of the present invention and should not be taken in a limiting sense.

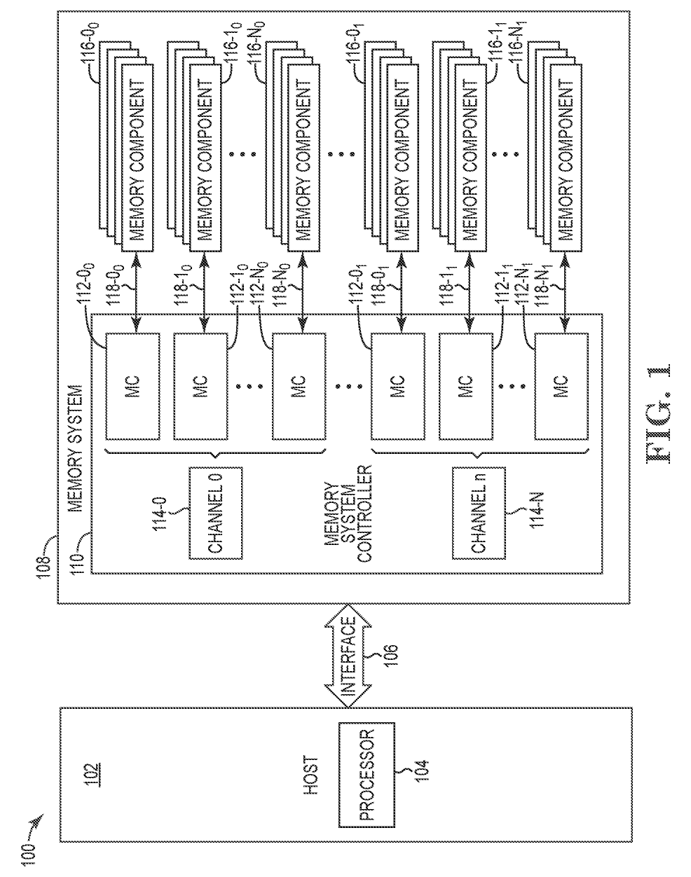

FIG. 1 is a block diagram of a computing system 100 including a memory system 108, a memory system controller 110, and a plurality of memory components 116-0₀, 116-1₀, 116-N₀, 116-0₁, 116-1₁, 116-N₁, collectively referred to as memory components 116, capable of implementing a number of embodiments of the present disclosure. The memory system controller 110 includes a plurality of memory channel controllers (e.g., MC) 112-0₀, 112-1₀, 112-N₀, 112-0₁, 112-1₁, 112-N₁, collectively referred to as memory channel controllers 112, for interfacing with memory components 116 corresponding to the respective memory channels 114-0, 114-N. The computing system 100 includes a host 102 and a processor 104. The computing system 100 can be a laptop computer, personal computer, digital camera, digital recording and playback device, mobile telephone, PDA, memory card reader, interface hub, sensor, Internet-of-Things (IoT) enabled device (e.g., thermostats, bulbs, locks, security systems, toothbrushes, pet feeders, etc.), among other systems, and the host 102 can include a number of processing resources 104 (e.g., one or more processors) capable of accessing the memory system 108 (e.g., via the memory system controller 110). The host 102 may be responsible for execution of an operating system (OS) and/or various applications that can be loaded thereto (e.g., from the memory system 108 via the memory system controller 110).

Although not shown in FIG. 1, the memory system controller can include a physical layer (PHY) for interfacing with the host 102 over interface 106, which can include a number of input/output (I/O) lines. The interface 106 can include various combinations of data, address, and control buses, which can be separate buses or one or more combined buses. In at least one embodiment, the interface 106 between the memory system controller 110 and the host 102 can be a peripheral component interconnect express (PCIe) physical and electrical interface operated according to a compute express link (CXL) protocol. In embodiments in which the interface 106 is operated under CXL protocol, the memory system controller 110 is configured to receive (e.g., from the host) memory access requests directed at the memory devices 116, and to provide (e.g., to the host) memory access responses corresponding to the memory access requests, according to CXL protocol. As non-limiting examples, the interface 106 can be a PCIe 5.0 interface operated in accordance with a CXL 2.0 specification or a PCIe 6.0 interface operated in accordance with a CXL 3.0 specification.

CXL is a high-speed central processing unit (CPU)-to-device and CPU-to-memory interconnect designed to accelerate next-generation data center performance. CXL technology maintains memory coherency between the CPU memory space and memory on attached devices such as accelerators, memory buffers, and smart I/O devices, which allows resource sharing for higher performance, reduced software stack complexity, and lower overall system cost. CXL is designed to be an industry open standard interface for high-speed communications, as accelerators are increasingly used to complement CPUs in support of emerging applications such as artificial intelligence and machine learning. CXL technology is built on the PCIe infrastructure, leveraging PCIe physical and electrical interfaces to provide advanced protocol in areas such as input/output (I/O) protocol, memory protocol (e.g., initially allowing a host to share memory with an accelerator), and coherency interface. CXL provides protocols with I/O semantics similar to PCIe (e.g., CXL.io), caching protocol semantics (e.g., CXL.cache), and memory access semantics (CXL.mem). CXL can support different CXL device types (e.g., Type 1, Type 2, and Type 3) supporting the various CXL protocols. Embodiments of the present disclosure are not limited to a particular CXL device type.

The memory system controller 110 may receive memory requests (e.g., in the form of read and/or write commands, which may be referred to as load and store commands, respectively) from the host 102. The memory system controller 110 can transfer commands and/or data between the host 102 and the memory system 108 over a number of interfaces, which can comprise physical interfaces such as buses, for example, employing a suitable protocol. Such a protocol may be custom or proprietary, or interfaces may employ a standardized protocol, such as Peripheral Component Interconnect Express (PCIe), Gen-Z, CCIX, or the like. The memory system controller 110 can comprise control circuitry, in the form of hardware, firmware, or software, or any combination of the three. As an example, the memory system controller 110 can comprise a state machine, a sequencer, and/or some other type of control circuitry, which may be implemented in the form of an application specific integrated circuit (ASIC) coupled to a printed circuit board. In a number of embodiments, the memory system controller 110 may be co-located with the host 102 (e.g., in a system-on-chip (SOC) configuration). Also, the memory system controller 110 may be co-located with the memory system 108.

The memory system 108 can comprise a number of physical memory “chips,” or dice which can each include a number of arrays (e.g., banks) of memory cells and corresponding support circuitry (e.g., address circuitry, I/O circuitry, control circuitry, read/write circuitry, etc.) associated with accessing the array(s) (e.g., to read data from the arrays and write data to the arrays). As an example, the memory system 108 can include a number of DRAM devices, SRAM devices, PCRAM devices, RRAM devices, FeRAM, phase-change memory, 3DXpoint, and/or Flash memory devices. In a number of embodiments, the memory system 108 can serve as main memory for the computing system 100.

The memory system controller 110 can be responsible for controlling various operations associated with executing memory access requests (e.g., read commands and write commands) from the host 102. For example, although not shown in FIG. 1, the memory system controller 110 can include a cache and various error circuitry (e.g., error detection and/or error correction circuitry) capable of generating error detection and/or error correction data for providing data reliability among other functionality in association with writing data to and/or reading data from the memory components 116, which can also be referred to as memory devices 116.

As described above, the memory system controller can include a number of memory channel controllers (e.g., media controllers) and a physical (PHY) layer that couples the memory system controller 110 to the memory devices 116. As used herein, the term “PHY layer” generally refers to the physical layer in the Open Systems Interconnection (OSI) model of a computing system. The PHY layer may be the first (e.g., lowest) layer of the OSI model and can be used to transfer data over a physical data transmission medium. In various embodiments, the physical data transmission medium includes memory channels 118-0₀, 118-1₀, 118-N₀, 118-0₁, 118-1₁, 118-N₁, collectively referred to as memory channels 118. The memory channels 118 can be, for example, 16-bit channels each coupled to 16-bit (e.g., x16) devices, to two 8-bit (x8) devices; although embodiments are not limited to a particular interface. As another example, the channels 118 can each also include a two pin data mask inversion (DMI) bus, among other possible bus configurations. The memory system controller 110 can exchange data (e.g., user data and error detection and/or correction data) with the memory devices 116 via the physical pins corresponding to the respective memory channels 118. As described further herein, in a number of embodiments, the memory channels 118 can be organized as a number of channel groups, with the memory channels of each group being accessed together in association with executing various memory access operations and/or error detection and/or correction operations.

As shown in FIG. 1, the memory system controller 110 includes a plurality of memory channel controllers 112 for interfacing with memory components 116 corresponding to the respective memory channels 114. In this example, the memory channels 114 are organized as a number of channel groups 114-0 …, 114-N. Each channel group 114 comprises “N” memory channels 118. For instance, channel group 114-1 comprises memory channels 118-0₀, 118-1₀, …, 118-N₀, and channel group 114-N comprises memory channels 118-0₁, 118-1₁, …, 118-N₁. Although each channel group is shown as comprising the same quantity of memory channels 118, embodiments are not so limited.

In this example, the memory channel controllers 112-0₀, 112-1₀, …, 112-N₀ corresponding to channel group 114-1 are coupled to respective memory components 116-0₀, 116-1₀, …, 116-N₀ via respective memory channels 118-0₀, 118-1₀, …, 118-N₀. In another example, the memory channel controllers 112-0₀, 112-1₀, …, 112-N₀ can be implemented as a single memory channel controller driving “N” memory channels. Although not shown in FIG. 1, the memory system controller may include a PHY memory interface for coupling to the memory components 116. The channel groups 114-0…114-N can be operated independently by the memory system controller 110 such that memory access requests and/or error operations can be separately (and concurrently) performed on the memory components 116 corresponding to the respective channel groups 114.

In a number of embodiments, the memory components 116 may be DRAM memory devices, as described above. The memory components 116 may be arranged in ranks such that there are a number of memory components 116 coupled to a same memory channel controller 112. For example, a memory rank may consist of a group of DRAM chips that share the same chip select, or activation, signal. When the memory controller activates the chip select line, all the DRAM chips in that rank respond to the command simultaneously. Memory systems can be arranged in ranks of one, two, or more. In this example, memory components 116 are arranged in a rank of four, although embodiments are not so limited.

The memory devices 116 can include multiple memory arrays which can be grouped into one or more banks. The memory banks can each contain individual rows of memory cells that can store data associated with memory devices 116 or can have data written thereto.

Although not shown, data buses, including address buses and/or command buses can couple the memory components 116 to the memory system controller 110. The data buses can be configured to transfer data from the memory components 116 to the memory system controller 110 and/or to transfer data from the memory system controller 110 to the memory components 116. The command buses can be configured to provide commands from the controller 110 to the memory components 116. The commands can include, for example, read commands and/or write commands, among other possible commands that can be provided to the memory components 116. The address buses can include address information associated with the commands. For example, an address associated with a read command can be provided via address buses connected to memory devices 116 and memory system controller 110. The memory devices 116 can provide data responsive to receiving and/or processing the read command.

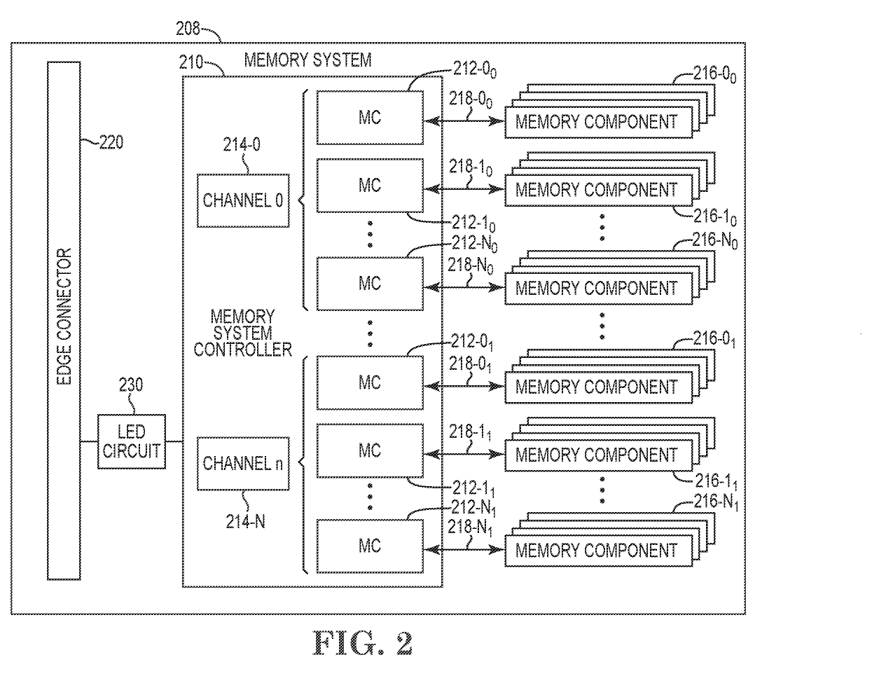

FIG. 2 illustrates a block diagram of a memory system 208 including an edge connector 220 and a light emitting diode (LED) circuit 230 in accordance with a number of embodiments of the present disclosure. Memory system 208 includes memory system controller 210 and a plurality of memory components 216-0₀, 216-1₀, 216-N₀, 216-0₁, 216-1₁, 216-N₁, collectively referred to as memory components 116 (as described in association with FIG. 1), capable of implementing a number of embodiments of the present disclosure. The memory system controller 210 includes a plurality of memory channel controllers (e.g., MC) 212-0₀, 112-1₀, 112-N₀, 212-0₁, 212-1₁, 212-N₁, collectively referred to as memory channel controllers 212, for interfacing with memory components 216 corresponding to the respective memory channels 214-0, 214-N (as described in association with FIG. 1).

Edge connector 220 can be configured to receive signals from host (via interface 106 illustrated in FIG. 1). Signals from the host can be transferred to memory system controller 210 via the edge connector 220. LED circuit 230 can be coupled to edge connector 220 and to memory system controller 210. LED circuit 230 can be coupled to a pin (e.g., a GPIO pin) on edge connector 220 and to a pin (e.g., a GPIO pin) on memory system controller 220. LED circuit 230 can include components such that outputs on the pin of memory system controller 210 coupled to LED circuit 230 are dependent on inputs on the pin of edge connector 220 coupled to LED circuit 230. Outputs on the pin of memory system controller 210 coupled to LED circuit 230 and inputs on the pin of edge connector 220 coupled to LED circuit 230 can be used to determine (e.g., detect) whether faults or failures exist in the LED circuit.

In a number of embodiments, LED circuit 230 can be used to send commands from the host to memory system controller 210 via pulse code. LED circuit 230 can be used for asynchronous serial inputs from the host to the memory system controller 210. The host can send signal pulses that correspond to binary inputs of commands that can be received, stored, and executed by memory system controller 210.

In a number of embodiments, a plurality of LED circuits 230 can be coupled to memory system controller 210. The plurality of LED circuits can have pins coupled to the edge connector 220, memory system controller 210, and/or other components on the memory system 208 that are configured to detect faults or failures according to embodiments of the LED circuit 230 described herein.

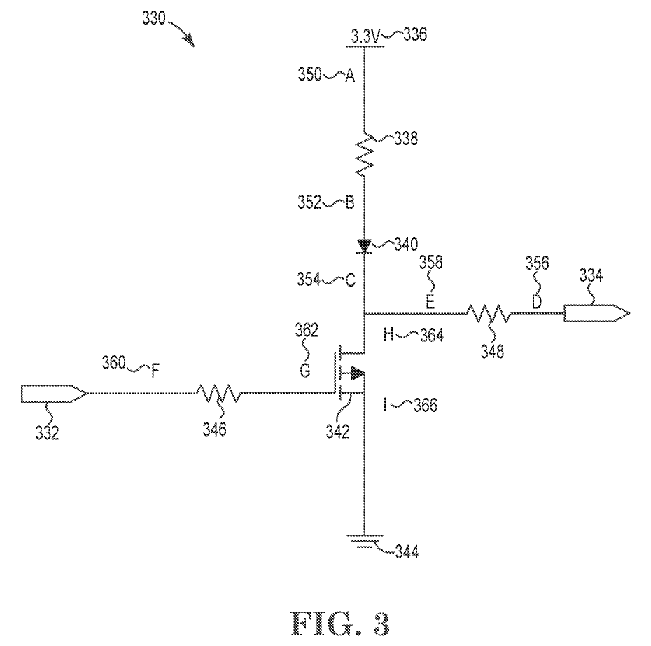

FIG. 3 illustrates a schematic diagram of a light emitting diode (LED) circuit 330 in accordance with a number of embodiments of the present disclosure. LED circuit 330 can be coupled to pin 332 (e.g., a GPIO pin) on edge connector (e.g., edge connector 220 illustrated in FIG. 2). LED circuit 330 can be coupled to pin 334 (e.g., a GPIO pin) on memory system controller (e.g., memory system controller 110/210 illustrated in FIGS. 1 and 2). Pin 322 can be coupled to a resistor 346 and resistor 346 can be coupled to a gate of transistor 342. Voltage source 336 can be coupled to resistor 338 and resistor 338 can be coupled to an input of LED 340. The output of LED 340 can be coupled to a drain of transistor 342 and coupled to resistor 348. Resistor 348 can be coupled to pin 334 on memory system controller. The source of transistor 342 can be coupled to ground 344.

Inputs detected at pin 332 and outputs at pin 334 can be used to detect faults or failures in LED circuit 330. Faults or failures in LED circuity can be a number of locations in LED circuits. Locations of faults or failures in LED circuity can be at Location A 350 between voltage source 336 and resistor 338, Location B 352 between resistor 338 and LED 340, Location C 354 between diode 340 and transistor 342, Location D 356 between resistor 348 and pin 334, Location E 358 between LED 340 and resistor 348, Location F 360 between pin 332 and resistor 346, Location G 362 between resistor 346 and transistor 342, Location H 364 between resistor 348 and transistor 342, and/or Location I 366 between transistor 342 and ground 344.

When LED circuit does not have a fault or failure, an input signal from a host can be placed on pin 332 turning on transistor 342 and causing transistor 342 to provide low resistance to ground and sinking the current from voltage source 336 through resistor 338 and LED 340 to ground 344. When the current from voltage source 336 is sunk to ground 344 through resistor 338, LED 340, and transistor 342, pin 334 detects a signal at a low level (e.g., a voltage or current that corresponds to an absence of a signal from a voltage source).

In the absence of a signal from a host on pin 332, transistor 342 is turned off and the current from voltage source 336 is not sunk to ground but is receive by pin 334 causing pin 334 to detect a signal at a high level (e.g., a voltage or current that corresponds to a signal from a voltage source).

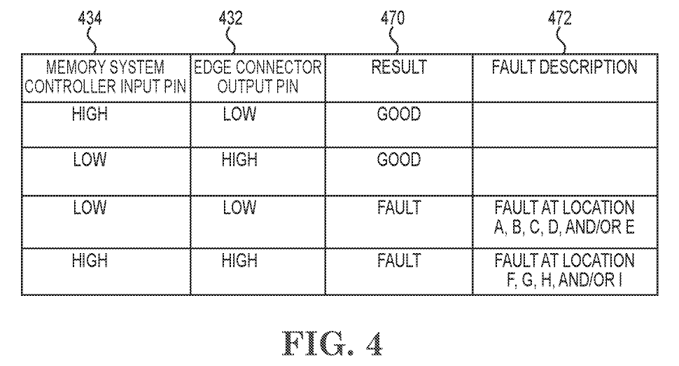

FIG. 4 illustrates a logic table associated with the inputs and outputs of a light emitting diode (LED) circuit in accordance with a number of embodiments of the present disclosure. The memory system controller can determine (e.g., detect) if fault or failures are present in the LED circuit.

When a signal at the pin on the edge connector 432 at a low level (e.g., a voltage or current that corresponds to a signal from the host) is detected and a signal at the pin on the memory controller 434 at a high level (e.g., a voltage or current that corresponds to an absence of a signal from a voltage source) is detected, the result 470 of the fault or failure determination is good and the memory system controller can determine (e.g., detect) that a fault or failure in the LED circuit does not exist. When a signal at the pin on the edge connector 432 at a high level (e.g., a voltage or current that corresponds to an absence of a signal from the host) is detected and a signal at the pin on the memory controller 434 at a low level (e.g., a voltage or current that corresponds to a voltage source) is detected, the result 470 of the fault or failure determination is good the memory system controller can determine (e.g., detect) that a fault or failure in the LED circuit does not exist.

When a signal at the pin on the edge connector 432 at a low level (e.g., a voltage or current that corresponds to an absence of a signal from the host) is detected and a signal at the pin on the memory controller 434 at a low level (e.g., a voltage or current that corresponds to an absence of a signal from a voltage source) is detected, the result 470 of the fault or failure determination indicates a fault the memory system controller can determine (e.g., detect) that a fault or failure in the LED circuit exists. The fault description 472 can be Locations A, B, C, D, and/or E in the LED circuit (as illustrated in FIG. 3) in response to a fault determination based on a signal at the pin on the edge connector 432 at a low level and a signal at the pin on the memory controller 434 at a low level.

When a signal at the pin on the edge connector 432 at a high level (e.g., a voltage or current that corresponds to a signal from the host) is detected and a signal at the pin on the memory controller 434 at a high level (e.g., a voltage or current that corresponds to a signal from a voltage source) is detected, the result 470 of the fault or failure determination indicates a fault and the memory system controller can determine (e.g., detect) that a fault or failure in the LED circuit exists. The fault description 472 can be Locations F, G, H, and/or I in the LED circuit (as illustrated in FIG. 3) in response to a fault determination based on a signal at the pin on the edge connector 432 at a high level and a signal at the pin on the memory controller 434 at a high level.

Although specific embodiments have been illustrated and described herein, those of ordinary skill in the art will appreciate that an arrangement calculated to achieve the same results can be substituted for the specific embodiments shown. This disclosure is intended to cover adaptations or variations of a number of embodiments of the present disclosure. It is to be understood that the above description has been made in an illustrative fashion, and not a restrictive one. Combination of the above embodiments, and other embodiments not specifically described herein will be apparent to those of ordinary skill in the art upon reviewing the above description. The scope of a number of embodiments of the present disclosure includes other applications in which the above structures and methods are used. Therefore, the scope of a number of embodiments of the present disclosure should be determined with reference to the appended claims, along with the full range of equivalents to which such claims are entitled.

In the foregoing Detailed Description, some features are grouped together in a single embodiment for the purpose of streamlining the disclosure. This method of disclosure is not to be interpreted as reflecting an intention that the disclosed embodiments of the present disclosure have to use more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separate embodiment.

What is claimed is:

1. A method comprising:
detecting an input voltage or an input current at a pin on a memory system controller, wherein the pin on the memory system controller is coupled to a circuit including a light emitting diode (LED);
detecting an output voltage or an output current at a pin on a memory system edge connector, wherein the pin on the memory system edge connector is coupled to the circuit; and
detecting whether a fault exists in the circuit based on the detected input voltage or input current at the pin on the memory system controller and the detected output voltage or the output current of the pin on the memory system edge connector.

2. The method of claim 1, further comprising detecting that a fault in the circuit does not exist in response to determining that the detected input voltage or input current at the pin on the memory system controller is at a high level and the detected output voltage or the output current of the pin on the memory system edge connector is at a low level.

3. The method of claim 1, further comprising detecting that a fault in the circuit does not exist in response to determining that the detected input voltage or input current at the pin on the memory system controller is at a low level and the detected output voltage or the output current of the pin on the memory system edge connector is at a high level.

4. The method of claim 1, further comprising detecting that a fault in the circuit exists in response to determining that the detected input voltage or input current at the pin on the memory system controller is at a low level and the detected output voltage or the output current of the pin on the memory system edge connector is at a low level.

5. The method of claim 4, wherein the detected fault is on a path between a voltage source and the pin on the memory system controller.

6. The method of claim 1, further comprising detecting that a fault in the circuit exists in response to determining that the detected input voltage or input current at the pin on the memory system controller is at a high level and the detected output voltage or the output current of the pin on the memory system edge connector is at a high level.

7. The method of claim 6, wherein the detected fault is on a path between a drain of a transistor in the circuit and the pin on the memory system edge connector or at a source of the transistor coupled to ground.

8. An apparatus comprising:
a memory system including a memory device, a memory system controller, and an edge connector, wherein the memory system controller is configured to:
detect an input voltage or an input current at a pin on a memory system controller, wherein the pin on the memory system controller is coupled to a circuit including a light emitting diode (LED);
detect an output voltage or an output current at a pin on a memory system edge connector, wherein the pin on the memory system edge connector is coupled to the circuit; and
detect whether a fault exists in the circuit based on the detected input voltage or input current at the pin on the memory system controller and the detected output voltage or the output current of the pin on the memory system edge connector.

9. The apparatus of claim 8, wherein the memory controller is configured to detect that a fault in the circuit does not exist in response to the detected input voltage or input current at the pin on the memory system controller being at a high level and the detected output voltage or the output current of the pin on the memory system edge connector being at a low level.

10. The apparatus of claim 8, wherein the memory controller is configured to detect that a fault in the circuit does not exist in response to the detected input voltage or input current at the pin on the memory system controller being at a low level and the detected output voltage or the output current of the pin on the memory system edge connector being at a high level.

11. The apparatus of claim 8, wherein the memory controller is configured to detect that a fault in the circuit exists in response to the detected input voltage or input current at the pin on the memory system controller being at a low level and the detected output voltage or the output current of the pin on the memory system edge connector being at a low level.

12. The apparatus of claim 8, wherein the memory controller is configured to detect that a fault in the circuit exists in response to the detected input voltage or input current at the pin on the memory system controller being at a high level and the detected output voltage or the output current of the pin on the memory system edge connector being at a high level.

13. The apparatus of claim 8, wherein the memory controller is configured to receive commands at t a pin on a memory system controller based on a pulse code controlled by an output voltage or an output current at a pin on a memory system edge connector.

14. The apparatus of claim 13, wherein the apparatus includes another circuit including another LED and wherein the another circuit includes an input/output pin on the memory controller configured to supply an input voltage or an input current to the another circuit.

15. An apparatus comprising:
a memory system including a memory device, a memory system controller, and an edge connector, wherein a light emitting diode (LED) circuit is coupled to the edge connector and the memory controller and wherein the memory system controller is configured to:
detect that a fault in the LED circuit does not exist in response to an input voltage or input current at a pin on the memory system controller is at a different level as an output voltage or the output current of a pin on the memory system edge connector; and
detect that a fault in the LED circuit exists in response to the input voltage or input current at the pin on the memory system controller is at a same level as the output voltage or the output current of the pin on the memory system edge connector.

16. The apparatus of claim 15, wherein a fault exists when the input voltage or input current at the pin on the memory system controller and the output voltage or the output current of the pin on the memory system edge connector are both at a high level or both at a low level.

17. The apparatus of claim 15, wherein a fault does not exist when the input voltage or input current at the pin on the memory system controller is at a high level and the output voltage or the output current of the pin on the memory system edge connector is at a low level.

18. The apparatus of claim 15, wherein a fault does not exist when the input voltage or input current at the pin on the memory system controller is at a low level and the output voltage or output current of the pin on the memory system edge connector is at a high level.

19. The apparatus of claim 15, wherein the LED circuit includes an LED coupled to a power source and the LED coupled to a drain of a transistor.

20. The apparatus of claim 19, wherein the pin on the memory system edge connector is coupled to a first resistor and the first resistor is coupled to a gate of a transistor and wherein the pin on the memory system controller is coupled to a resistor and the resistor is coupled to an output of the LED.
